(19) United States
(12) Patent Application Publication
(10) Pub. No.: US 2005/0188923 A1
(43) Pub. Date: Sep. 1, 2005

(54) Substrate carrier for parallel wafer processing reactor

(76) Inventors: Robert C. Cook, Pleasanton, CA (US); Ronald Stevens, San Ramon, CA (US); Peter Schwartz, Livemore, CA (US); Cesar Tejamo, Stockton, CA (US); Vebjorn Nilsen, Dublin, CA (US); Gabriel Ormonde, Lathrop, CA (US); Ajit Paranjpe, Fremont, CA (US); Somnath Nag, Saratoga, CA (US); Michael Patten, Fremont, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 10/966,245

(22) Filed: Oct. 15, 2004

Related U.S. Application Data
(63) Continuation-in-part of application No. 10/216,079, filed on Aug. 9, 2002.
Application No. 10/216,079 is a continuation-in-part of application No. 09/954,705, filed on Sep. 10, 2001, now Pat. No. 6,780,464.
Application No. 09/954,705 is a continuation-in-part of application No. 09/396,588, filed on Sep. 15, 1999, now Pat. No. 6,287,635.
Application No. 10/216,079 is a continuation-in-part of application No. 08/909,461, filed on Aug. 11, 1997, now Pat. No. 6,352,593.
Application No. 10/216,079 is a continuation-in-part of application No. 09/228,835, filed on Jan. 12, 1999, now Pat. No. 6,167,837.
Application No. 10/216,079 is a continuation-in-part of application No. 09/228,840, filed on Jan. 12, 1999, now Pat. No. 6,321,680.
Application No. 10/216,079 is a continuation-in-part of application No. 09/396,590, filed on Sep. 15, 1999, now Pat. No. 6,506,691.
(60) Provisional application No. 60/100,594, filed on Sep. 16, 1998.
(60) Provisional application No. 60/071,572, filed on Jan. 15, 1998.
(60) Provisional application No. 60/071,571, filed on Jan. 15, 1998.
(60) Provisional application No. 60/100,596, filed on Sep. 16, 1998.

(51) Int. Cl. C23C 16/00

(52) U.S. Cl. 118/728

(57) ABSTRACT

A substrate carrier for a parallel wafer processing reactor supports a plurality of substrates. The substrate carrier includes a plurality of susceptors, which may be thermal plates or annular rings that are arranged horizontally in a vertical stack. The substrates are mounted between pairs of susceptors on two or more supports provided around the outer periphery of the susceptors. The number of substrates mounted between each pair of susceptors may the same or different but is two or more between at least one pair of susceptors.

### CROSS-REFERENCE TO RELATED APPLICATIONS

This application is a continuation-in-part of U.S. application Ser. No. 10/216,079, filed Aug. 9, 2002, which is a continuation-in-part of: (a) U.S. application Ser. No. 09/954,705, filed Sep. 10, 2001, now U.S. Pat. No. 6,780,464, which is a continuation-in-part of U.S. application Ser. No. 09/396,588, filed Sep. 15, 1999, now U.S. Pat. No. 6,287,635 (which claims the benefit of U.S. Provisional Application Ser. No. 60/100,594, filed Sep. 16, 1998), which is a continuation-in-part of: (i) U.S. application Ser. No. 08/909,461, filed Aug. 11, 1997, now U.S. Pat. No. 6,352,593, (ii) U.S. application Ser. No. 09/228,835, filed Jan. 12, 1999, now U.S. Pat. No. 6,167,837 (which claims the benefit of U.S. Provisional Application Ser. No. 60/071,572, filed Jan. 15, 1998), and (iii) U.S. application Ser. No. 09/228,840, filed Jan. 12, 1999, now U.S. Pat. No. 6,321,680 (which claims the benefit of U.S. Provisional Application Ser. No. 60/071,571, filed Jan. 15, 1998); and (b) U.S. application Ser. No. 09/396,590, filed Sep. 15, 1999, now U.S. Pat. No. 6,506,691 (which claims the benefit of U.S. Provisional Application Ser. No. 60/100,596, filed Sep. 16, 1998).

### BACKGROUND OF THE INVENTION

1. Field of the Invention

Embodiments of the present invention relate to the deposition of materials on multiple substrates, and more particularly to, an apparatus useful for chemical vapor deposition and atomic layer deposition during the fabrication of semiconductor devices.

2. Description of the Related Art

The fabrication of semiconductor devices involves the sequential deposition of various materials onto a substrate. Deposition may be accomplished through chemical vapor deposition (CVD), atomic layer deposition (ALD), or other methods. Such deposition steps take place in one or, more commonly, a series of process chambers. For example, the deposition of silicon may be accomplished by placing a substrate in a process chamber, heating the substrate to a desired temperature, and then introducing silane or a similar precursor such as disilane, dichlorosilane, silicon tetrachloride and the like, with or without other gases, into the process chamber. The precursor disassociates at the hot substrate surfaces resulting in silicon deposition.

It is desirable to increase throughput by adjusting operating parameters within the process chamber. Such parameters include pressure, temperature, deposition gas injection rate, purge gas volume, and so forth. At the same time, it is important to maintain quality of the layers in the fabricated semiconductor devices, such as providing uniform film thickness. Optimum quality control may be obtained by using a single wafer processing reactor, which includes a process chamber that performs one or more process steps on a single substrate. However, single wafer processing has limited throughput.

A parallel wafer processing reactor has been used to increase throughput. A parallel wafer processing reactor places a plurality of substrates into a vertical stack within the same reactor. Examples of a parallel wafer processing reactor are described in U.S. Pat. No. 6,352,593, U.S. Pat. No. 6,352,594, U.S. patent application Ser. No. 10/216,079, and U.S. patent application Ser. No. 10/342,151, all of which are incorporated by reference herein.

The parallel wafer processing reactor described in the above patents and patent applications allows for the deposition of silicon (or other material) simultaneously on multiple substrates arranged in parallel orientation to one another. It employs a multi-plenum temperature-controlled vertical injector to provide uniform gas flow across the wafer, and provides an isothermal wafer environment that results in good wafer temperature uniformity. These two features enable the deposition of a variety of films at relatively high deposition rates over a wide process space. As a consequence, it provides the process benefits of single wafer processing reactors (i.e., uniform, high quality films, large process windows, low cycle times, multi-step sequential processing, vacuum integrated processing and flexible lot sizes), while processing numerous substrates at a time to increase throughput.

### SUMMARY OF THE INVENTION

Embodiments of the present invention provide a substrate carrier for a parallel wafer processing reactor that further increases process throughput. In one embodiment, the substrate carrier includes a plurality of susceptors arranged horizontally in a vertical stack. The substrates are mounted between pairs of susceptors on two or more supports provided around the outer periphery of the susceptors. The number of substrates mounted between each pair of susceptors may be the same or different but is two or more between at least one pair of susceptors.

Embodiments of the present invention also provide a parallel wafer processing reactor for processing substrates. The reactor includes a process chamber and a substrate carrier having a plurality of horizontally arranged susceptors and a support, disposed between at least one pair of said susceptors, for holding at least two substrates.

In one embodiment of the present invention, the support between each pair of susceptors includes two opposing spacers. Opposite ends of the wafers are supported on these shoulders. In another embodiment of the present invention, the support between each pair of susceptors includes three spacers arranged so that first, second and third ends of the wafers are supported on these shoulders. The first, second and third ends of the wafers have radial positions on the wafer that are 120° from each other.

The substrate carrier according to embodiments of the present invention offers certain advantages over the prior art substrate carrier designs. They include an increase in capacity for substrates within a given isothermal zone, and a reduction in cost by decreasing the number of susceptors.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top cross-sectional view of a parallel wafer processing reactor as may be employed with certain features of the present invention.

FIG. 2 is an enlarged view of a substrate carrier in accordance with one embodiment of the present invention.

FIG. 3 is an enlarged, partial perspective view of a substrate carrier of FIG. 2.

FIG. 4 is an enlarged, cross-sectional view of spacers interlocked with susceptor posts.

FIG. 5 is a perspective view of a spacer.

FIGS. 6A and 6B illustrate alternate points on the wafer that are supported by spacers.

FIGS. 7A-7C present partial side views of alternate configurations for a substrate carrier.

FIG. 8 is a partial side view of an alternate configuration for a susceptor.

FIG. 9 is a graph showing process results achieved using a substrate carrier according to an embodiment of the invention.

FIG. 10 is a top cross-sectional view of a parallel wafer processing reactor with multiple gas injection manifolds.

FIG. 11 is a schematic diagram of a fixed volume delivery mechanism.

FIG. 12 is a flow diagram of a hybrid cleaning approach.

FIGS. 13-15 are illustrations of a wafer handling system used with a parallel wafer processing reactor.

### DETAILED DESCRIPTION

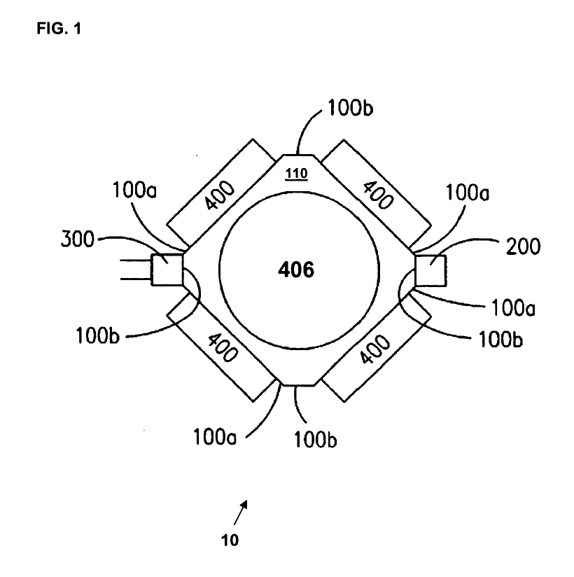

FIG. 1 provides a cross-sectional top view of a parallel wafer processing reactor 10 as may be employed with certain features of the present invention. The reactor 10 includes four walls 100a and four walls 100b that enclose a processing space 110. A gas injection manifold 200 and a gas exhaust manifold 300 are attached to opposite walls 100b. A multiple zone heating structure 400 is attached to each of the four side walls 100a. A substrate carrier for holding a plurality of wafers or substrates is illustrated as 406.

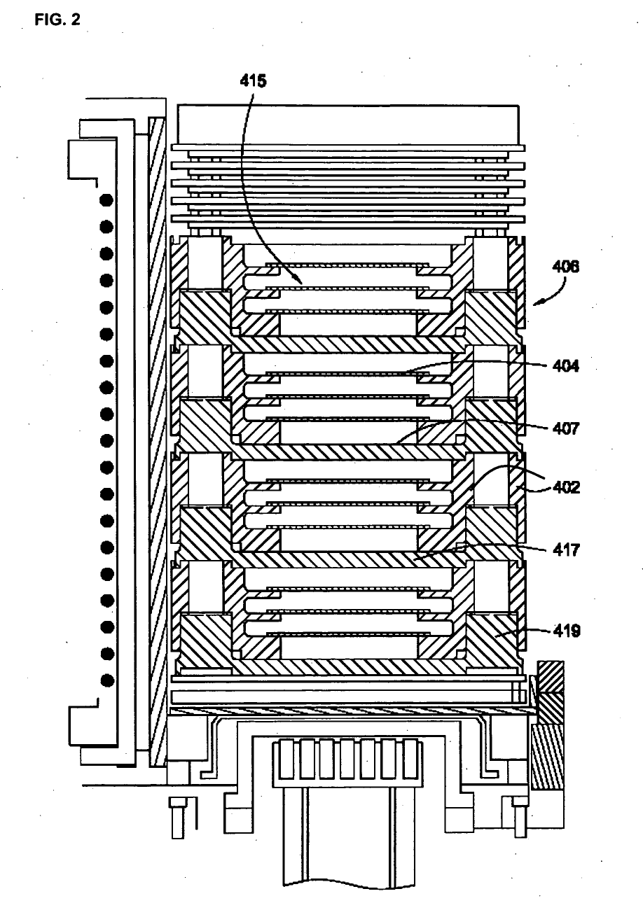

FIG. 2 provides an enlarged side view of a substrate carrier 406 in accordance with one embodiment of the present invention. The substrate carrier 406 generally defines an elongated cylindrical body. Openings 415 are formed along the longitudinal axis of the substrate carrier 406 between susceptors 407. Substrates 404 are placed in the openings 415 between pairs of susceptors 407 and mounted on shoulders that are formed on spacers 402.

The susceptors 407 are made up a generally planar platen 417 and two or more discrete post members 419 disposed radially around the platen. The platen portion 417 is designed to be heated, such as by means of a heating element (not shown). To accommodate heating of the platen 417, the susceptors 407 are preferably made from a refractory, high thermal conductivity material such as SiC coated graphite, SiC coated SiC or solid SiC. A variety of other materials may also be used, although various combinations of SiC and graphite appear to be optimal for high temperature applications. Preferably, the susceptors 407 have a larger diameter than the substrates 404. For some processes such as thermal annealing or oxidation, the susceptor diameter is equivalent to the substrate diameter.

The susceptors 407 play several important roles. The susceptors 407 pre-heat the process gases and induce a stable flow and stable thermal boundary layer before the gas flows reach the substrates 404, minimizing wafer edge effects. The thermal mass of the susceptors 407 also exceeds the thermal mass of the substrates 404. The susceptors 407 also help control the gas flow through the substrate carrier 406, reducing the need for dummy wafers. They also reduce the formation of flow eddies or zones of gas recirculation that may exacerbate gas phase formation of particles.

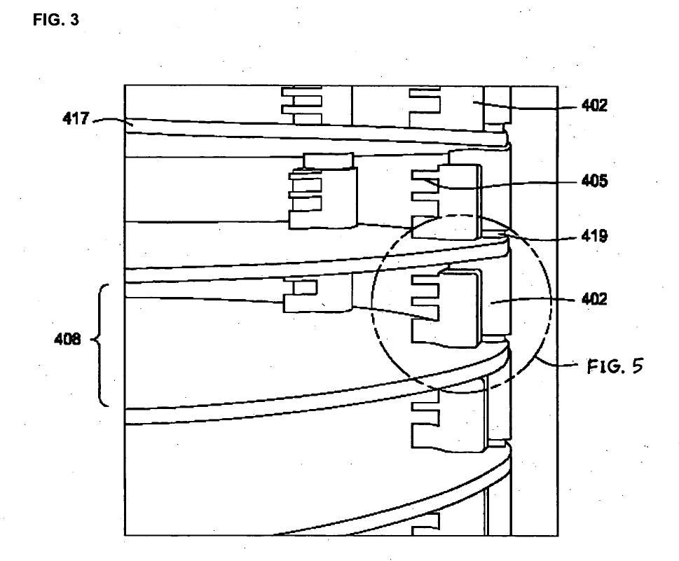

The susceptors 407 are vertically stacked so that the respective platens 417 are generally parallel to one another. FIG. 3 provides an enlarged, perspective view of a portion of the substrate carrier 406. In this view, the individual platens 417 and posts 419 are more clearly shown. It can also be seen from FIG. 3 that a gap 408 is formed between adjacent pairs of susceptors 407. The gaps 408 serve as individual isothermal cavities which produce uniform emissivity and pattern-independent heating of substrates 404 during loading and unloading. The isothermal cavities between the susceptors 407 simplify the implementation of pyrometry-based temperature monitoring and control. The substrates 404 placed within the gaps 408 are heated rapidly to the process temperature while maintaining excellent temperature uniformity across the substrates 404.

The geometrical variables associated with the susceptors 407 that influence process performance are: (a) clearance above and below each wafer, (b) the inter-susceptor spacing, and (c) the susceptor diameter. The optimal clearances above and below the substrate 404 are somewhat process dependent. Typically, equal clearances above and below the wafer result in the same film thickness and film properties on both sides of the wafer. This is generally desirable since wafers retain their flatness following deposition. The films on the backside of the wafer may be stripped at some point in the process flow. The distribution of gases above and below each wafer depends primarily on the clearances above and below the wafer. As the clearances are increased, a larger fraction of the process gases introduced through the gas injection manifold 200 (see FIG. 1) along the substrate carrier 406 flow across the front and back sides of the substrates 404 (rather than around the substrates) and, thence, into the gas exhaust manifold 300 (see FIG. 1).

For in situ doped Si films, the optimal clearance between the substrate 404 and the adjacent susceptor 407 is in the range of 0.15 inches to 0.30 inches to ensure that a proper amount of process gases flow across the substrates 404 rather than around the substrates 404. The substrates 404 may be placed away from the mid-plane of the gaps 408 to alter the ratio of gas flow over the substrates 404 to the gas flow under the respective substrates 404. The gaps 408 retain their isothermal near black body characteristics for intersusceptor spacings in the range of 0.25 inches to 1.25 inches for susceptors that are 13.6 inches in diameter (i.e. preferred minimum aspect ratio of the resulting gap 408 between susceptors is greater than 10:1).

It is desirable to increase the load size of the substrate carrier 406 without compromising the deposition rates, film uniformities, and film properties. Increasing load size is accomplished herein by placing more than one substrate 404 between each pair of susceptors 407. The clearances above and below each substrate 404 are selected to meet the desired process parameters as set forth above. By placing two, three, four or more substrates 404 instead of only one substrate 404 between adjacent susceptors 407, the load size can be increased without making other major changes to the reactor 10.

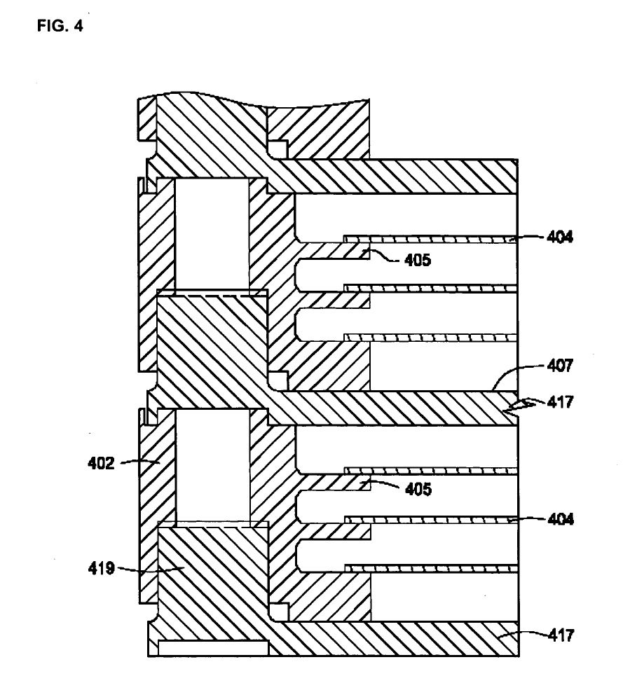

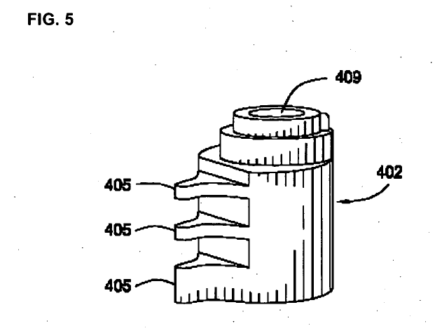

FIG. 4 shows a plurality of substrates 404 placed between the susceptors 407. In order to place a plurality of substrates 404 between the susceptors 407, shoulders 405 are provided along the height of the substrate carrier 406. More specifically, three shoulders 405 are provided between each pair of susceptors 407. The shoulders 405 support respective substrates 404 placed thereon and are formed on the spacers 402 provided between the susceptors 407. A single spacer 402 is shown in FIG. 5. In this arrangement, the spacer 402 has shoulders 405 that are integral with the spacer 402 and a through-hole 409 that extends the entire height of the spacer 402.

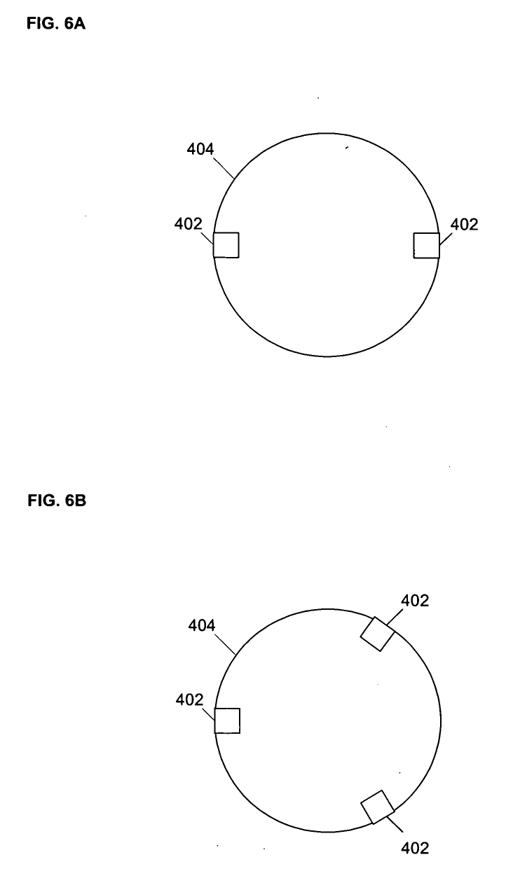

are used between two adjacent susceptors 407, the three spacers 402 support first, second and third ends of the substrates 404 that equidistant (120°) from one another. FIG. 6A illustrates the points of the substrates 404 that are supported when two spacers 402 are used. FIG. 6B illustrates the points of the substrates 404 that are supported when three spacers 402 are used.

FIG. 4 also provides an enlarged, cross-sectional view of spacers 402 interlocked with susceptor posts 419. Each spacer 402 is engaged with upper and lower susceptors 407. The top part of the spacer 402 is engaged with a recess formed on a bottom face of the upper susceptor 407 and the bottom opening of the spacer 402 is engaged with the post 419 of the lower susceptor 407. In FIG. 4, three substrates 404 are shown supported between each pair of susceptors 407. The placement of a plurality of substrates 404 between susceptors 407 may be implemented in several ways. For example, in some gaps a single substrate 404 could be inserted, while in other gaps more than one substrate 404 could be inserted. Thus, the number of substrates 404 between adjacent susceptors could vary along the height of the substrate carrier 406. In one embodiment, a larger number of substrates 404 may be placed in between each pair of susceptors 407 in a central region of the substrate carrier 406, and a fewer number may be placed between each pair of susceptors 407 towards opposite ends of the substrate carrier 406.

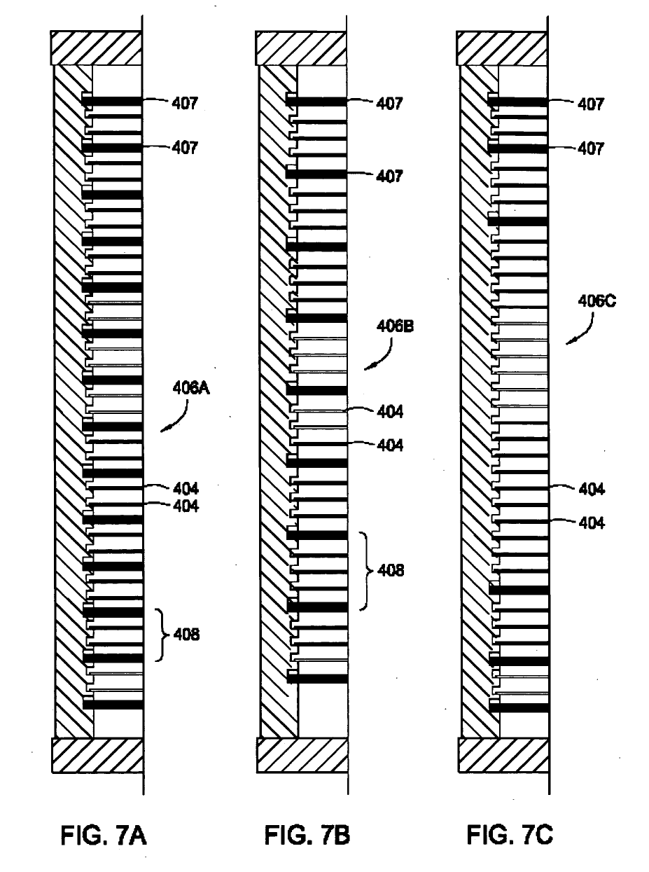

FIGS. 7A, 7B and 7C provide partial side view of substrate carriers 406A, 406B and 406C, respectively. The substrate carrier 406A of FIG. 7A is configured to hold two substrates 404 per gap 408, and to hold a total of 26 substrates. The substrate carrier 406B of FIG. 7B is configured to hold three substrates 404 per gap 408, and to hold a total of 27 substrates. Finally, the substrate carrier 406C of FIG. 7C is configured to hold different numbers of substrates 404 between the pairs of susceptors 407, and to hold a total of 31 substrates.

Optionally, objects serving as insulators or thermal conductors may be selectively placed between certain adjacent susceptors 407. Insulators would be of particular value when placed between susceptors 407 at the extremities of the substrate carrier 406 in order to reduce the heat loss from the top and bottom of the substrate carrier 406. A bottom and/or top heater can also optionally augment the heat flux to the bottom and/or top of the substrate carrier 406.

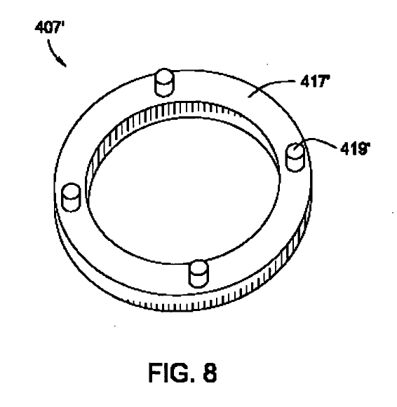

In a case where three substrates 404 are disposed between pair of susceptors 407, the substrates 404 closest to either susceptor 407 may heat up more quickly than the substrate 404 that is sandwiched between the two outer substrates 404. An embodiment of the invention illustrated in FIG. 8 mitigates this effect. In this embodiment, each susceptor 407′ has an annular configuration with a circular opening in the center that is slightly smaller than the diameter of the substrate 404, and comprises a thin, annular ring 417′ and a plurality of posts 419′ for interlocking with the spacers 402.

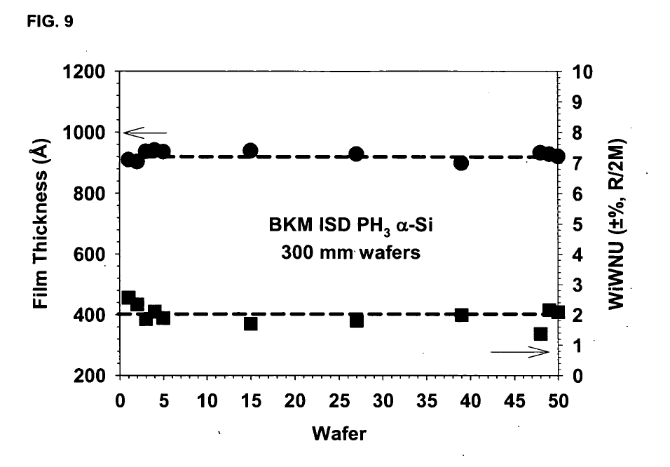

The process results for the substrate carrier 406 with four wafers per susceptor pair (50 wafers in total) are shown in FIG. 9. Results are shown for selected locations within the boat. The results show that good film uniformities can be achieved.

For many CVD and ALD processes, it is necessary to precisely control the temperature of the chamber walls. In many cases, the ideal temperature is an intermediate temperature between the process temperature and the room temperature. At the ideal temperature, there should be no condensation of precursors or reaction by-products, and films (if deposited) must be contiguous, low stress and not powder-like. These requirements are usually met at temperatures approaching the process temperature. Since the deposition rate generally falls off at lower temperatures, it is preferable to control the wall temperature to a value slightly below the process temperature so that the rate of build-up on the chamber walls is decreased. Eventually, the build-up on the chamber walls will be thick enough requiring a chamber clean. Since it is infeasible to remove the chamber for cleaning and in situ chamber cleaning may not remove the entire deposited film, one or more removable liners that cover the chamber wall may be used. The liners can be made from a variety of materials including SiC, SiC on SiC, SiC on graphite, anodized aluminum or composite structures comprising a refractory material and an insulating material such as SiO2, AIN, polymers, etc.

For liner surface temperatures above 300° C., the preferred material and method of construction is SiC, SiC on SiC, SiC on graphite that is closely spaced (0.25 mm-0.75 mm) away from a chamber wall maintained at a lower temperature. By controlling the gap between the liner and the chamber wall, the temperature of the liner and the outer skin of the chamber wall can be adequately controlled. This small gap provides thermal isolation, but is generally not large enough for the precursor or reaction by-products to accumulate in this cavity. For lower liner temperatures, the liner can be placed in contact with the chamber wall with an intervening insulator.

The liner has advantageous utility in both in situ cleaning and ex situ cleaning. For in situ cleaning, the liner may be cleaned through known steps for etching/removal of deposited films. For ex situ cleaning, the liner may be removed and cleaned or replaced, avoiding extensive cleaning of other chamber hardware.

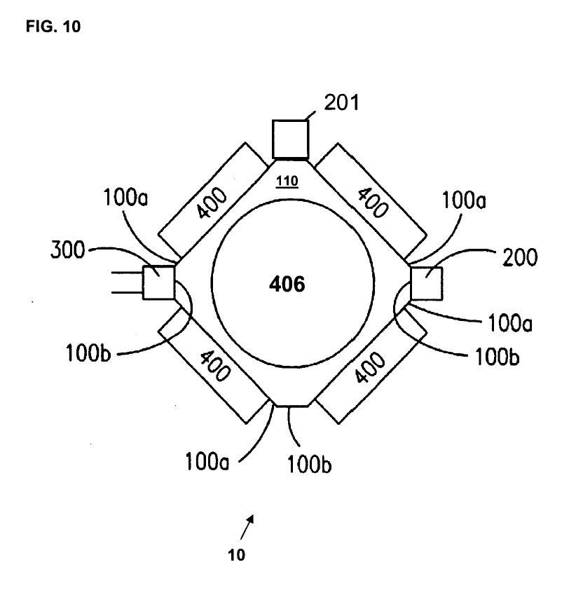

FIG. 10 illustrates a parallel wafer processing reactor 10 having an additional gas injection manifold 201 that functions as a secondary gas/precursor injector. The additional gas injection manifold 201 is spatially separated from the primary gas injection manifold 200. The temperature of the spatially separated gas injection manifolds 200, 201 are independently controlled and permit physical separation of those precursors that might react chemically during precursor delivery.

For some applications, a fixed volume delivery scheme may be necessary for more than one precursor. Since the fixed volume should be located in close proximity to the point of injection, space constraints limit the number of fixed volumes that can be mounted adjacent to an injector. In such cases, using multiple spatially separated injectors simplifies the integration task. Multiple, spatially separated injectors offer the following benefits:
Improved thermal management by mounting the assembly outside the actively heated region so that the temperature of the injector can be independently controlled;
Independent plenums for various precursors to minimize chemical interaction during precursor delivery;
Uniform gas flow velocity across the face of the injector due to a relatively large number of holes in the injector plate compared to conventional multi-port injection;
Allows efficient introduction and evacuation of precursors while reducing cross-contamination issues between precursors; and
Enables more efficient packaging of components: reduces plumbing required to deliver volatile precursors, saves space, increases service access, and improves reliability by reducing complexity.

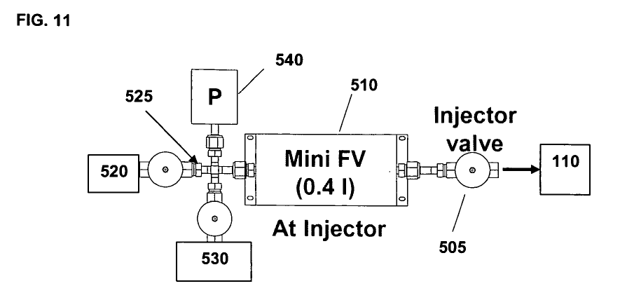

The fixed volume delivery mechanism, illustrated in FIG. 11, has been expanded to incorporate additional operating modes, some of which have been made feasible by placing the fixed volume in close proximity to the injector. Some of the modes of operation of the fixed volume delivery are described below:
Fill→[Top]→Dose→[Pump]: The steps in [ ] are optional. In this mode, dosing of the precursor into the reaction space 110 through an injector valve 505 is achieved by: (a) filling the fixed volume 510 to a ‘fill’ pressure using vapor-draw or bubbler mode from an ampoule 520 containing the liquid precursor; (b) topping the fixed volume 510 with N₂ push gas 530 to a topping pressure; (c) emptying or dosing the precursor from the fixed volume 510 into the reaction space 110 with a short pulse during which the pressure in the fixed volume 510 drops as the precursor is transferred to the reaction space 110; and (d) pumping the fixed volume 510 to a known pressure using a pump 540 prior to repeating the filling step. The pressure of the reaction space 110 is controlled during the dose step to ensure uniform surface reaction across the wafer.
Fill→Push/Dose→Pump: In this mode, dosing of the precursor into the reaction space 110 through an injector valve 505 is achieved by: (a) filling the fixed volume 510 to a fill pressure using vapor-draw or bubbler mode from an ampoule 520 containing the liquid precursor; (b) dosing the precursor from the fixed volume 510 into the reaction space 110 by forcing it with N₂ push gas 530; and (d) pumping the fixed volume 510 to a known pressure prior to repeating the filling step. The pressure of the reaction space 110 is controlled during the dose step to ensure uniform surface reaction across the wafer. In this mode, the fixed volume 510 may be pumped by the chamber rather than a dedicated line.
Flow to Chamber: In this mode, the precursor is delivered as a continuous flow stream to the reaction space 110 during the dosing step analogous to a CVD process. The precursor is drawn into the reaction space 110 via a vapor draw or a bubbler mode.

The flow to the fixed volume 510 can optionally be metered using a flow monitor or flow controller 525 such as a low pressure mass flow controller (for vapor draw) or a mass flow monitor (for bubbler mode). The mass flow monitor 525 measures the flow rate of precursor in the carrier stream and may optionally adjust the carrier flow or bubbler operating conditions to maintain a constant flow rate of precursor. In an actual implementation, additional fixed volume states denoting when the fixed volume 510 is idle, isolated or sealed, filled, topped or pumped may be used during operation.

The parallel wafer processing reactor 10 described herein also enables epitaxial and selective epitaxial deposition of semiconductor films. Low temperature epitaxial and selective epitaxial deposition of silicon and silicon germanium films is becoming increasingly important for next generation semiconductor devices. The parallel wafer processing reactor 10 described herein can be extended to accomplish the deposition of such films. The parallel wafer processing reactor 10 is suitable for epi processing because it possesses several of the essential attributes for epi processing such as uniform distribution of dopants across the wafer and across the entire wafer load, ability to deliver radicals, and suppression of oxide re-growth. The attributes of the parallel wafer processing reactor 10 that enable epitaxial processing are listed below:
Parallel wafer processing and cross wafer gas flow chamber architecture results in uniform dopant content (<1 atomic %) in polysilicon and α-SiGe films.
Quartz liner within outer aluminum chamber (annular cavity is purged with filtered high purity inert gas) for compatibility with chlorinated chemistries, in situ clean and bake-out. The cylindrical quartz liner has multiple ports arranged around its periphery. The injector is mounted on one port while the exhaust flange is connected to the diametrically opposed port. A third port can be used to house the pyrometers for temperature sensing. The differentially pumped cavity improves the integrity of the vacuum within the quartz liner and also controls the heat loss to the outer aluminum chamber walls.
Multi-wafer low thermal mass boat and low thermal mass, high temperature capable thermal diffusion shields to achieve>50° C./min ramps from 600-750° C. for optional pre-epi gas phase cleaning. The low thermal mass, high temperature shields can wrap around the quartz liner in between the ports on the liner. In the CVD version of the reactor, the shields are mechanically sealed against a quartz window and the cavity formed between the shields and the quartz window is purged with an inert gas.
Radical generator (e.g. H) integrated into injector for<750° C. pre-clean. Various types of electrode-less discharges such as microwave excited surface wave or slot antenna excited discharges can be built into the injector. The surface wave discharge consists of a dielectric tube (e.g. quartz) that is placed within the injector housing. The tube is capped at one end and is connected to a gas feed that is external to the vacuum chamber. An antenna that excites a surface wave is placed at the end of the dielectric tube that exits the chamber. Gas fed into the tube is excited into radicals by the plasma sustained within the tube and exits the tube through a pattern of fine holes along the length of the tube resulting in a uniform flux of radicals along the length of the boat. A multiplicity of such radical sources can be used to either increase the capacity of the radical generation system or to provide multiple types of radicals.
Point-of-use purifiers for all process and purge gases with gas line bake-out capability to achieve an effective moisture and oxygen content of<1 ppb within the process chamber.
Turbo pump installed on the exhaust port to achieve a base pressure of<2×10⁻⁶ Torr while a conventional high capacity pump is used to control the chamber pressure during the process.
Native oxide re-growth can be suppressed by loading and unloading wafers and heating up the wafers in a reducing (N₂/H₂) ambient.
Low pressure (1-10 Torr) processes with large excess of H₂ are generally beneficial at sub-600° C. At these temperatures deposition rates may have to be constrained to 10 Å/min to retain high film quality and selectivity. Higher order silanes (or derivatives) may also be necessary at lower temperatures. These include disilane, trisilane and associated halogenated derivatives with or without intrinsic carbon content and carbon containing additives.
The queue time between HF last wet clean and process start is preferably<30 min.

In situ chamber cleaning which involves the etching/removal of deposited films from the reactor surfaces is widely used in single wafer processing reactors. The alternative cleaning methodology is ex situ cleaning in which the process chamber is opened, parts with deposited film are swapped with clean parts, and the chamber is physically wiped down. Ex situ cleaning by its very nature is time consuming because it involves venting of the chamber to atmosphere, replacement of components, and an extended chamber qualification/conditioning before processing of wafers can begin. For thermal systems, the overhead associated with cool-down of the system prior to venting and heat-up of the system following the ex situ clean add to the overall down-time. If the chamber has been exposed to toxic gases during wafer processing, gas specific abatement procedures may have to be performed before the reactor can be opened for servicing. For these reasons, in situ chamber cleaning is advantageous over ex situ chamber cleaning.

In one approach for in situ cleaning, the boat is allowed to cool-down in the upper chamber while etching gases are introduced in the process chamber to etch the films off the thermal diffusion shields and the liners (if installed). Once the films have been etched off the shields and the liners, the boat is re-introduced into the process chamber and the boat can be cleaned in situ or processing can resume. In this type of reactor, the deposition on the thermal diffusion shields exceeds the deposition on the boat by a factor of 1.5×-3× depending on the process conditions and the temperature differential between the thermal diffusion shields and the boat. Thus the boat is not cleaned as frequently as the thermal diffusion shields.

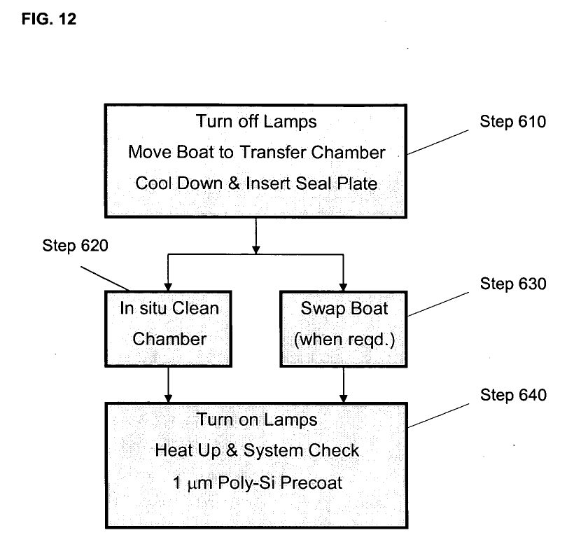

In a hybrid in situ cleaning approach, illustrated in FIG. 12, a seal plate is used to isolate the process and upper chambers once the boat is moved to the upper chamber (Step 610). Once the process chamber is sealed off, the thermal diffusion shields and liners are subjected to an in situ clean to etch off the deposited film (Step 620). In parallel, the boat can be swapped with a pre-built clean boat if necessary (Step 630). In Step 640, the lamps are turned on and the system is checked. A 1 micron thick polysilicon precoat layer is also deposited. As discussed before, the boat does not have to be cleaned as frequently as the thermal diffusion shields.

A variety of etching gases have been used for in situ cleaning including NF₃, atomic fluorine, F₂, chlorofluorocarbons, CIF₃, HF, HCI, etc. These gases are suitable for use in the parallel wafer processing reactor 10 described herein except that the etch rate, surface temperatures, and compatibility with reactor materials must be considered. Very low etch rates are generally unacceptable since they translate to very long in situ clean times that effectively degrade system uptime in a production environment. Many fluorinated and chlorinated gases attack metallic surfaces, polymeric materials and coatings (e.g. SiC, AIN) above a certain threshold temperature. Attack not only causes corrosion, but low volatility metal fluorides/chlorides can remain resident in the reactor and contaminate the film during subsequent processing. Typically surfaces temperatures should be below 300° C. to avoid attack of metallic surfaces and SiC. Quartz components are relatively immune to attack and can sustain substantially higher temperatures without being etched appreciably.

Atomic fluorine can be generated via a variety of methods. A conventional approach is to flow a fluorine containing gas through a plasma source. Alternatively, the fluorine containing gas can be introduced into the plasma plume downstream of the plasma source where the ions, excited atoms/molecules, and radicals formed in the plasma source dissociate the fluorine containing gases to generate atomic fluorine. The plasma source can be designed so that the plasma plume is intentionally very long. Introducing reactants downstream of the plasma source may result in more efficient dissociation into species that are effective in etching. For example in the case of CF₄, complete dissociation into CF and F atoms may be less effective at etching SiO₂ compared to a partial dissociation into CF₂ and F. Adding the cleaning gas to the plasma source may also damage the source via etching of the plasma containing tube. In either case, the plasma source may be pulsed to enhance the atomic fluorine generation rate. Pulsing the plasma source allows high power levels to be used for short periods of time without overheating the plasma source. Plasma pulsing is also a means to control the types of radicals formed. Instead of using a plasma source, atomic fluorine can also be generated by thermally cracking a fluorine containing gas using a hot filament.

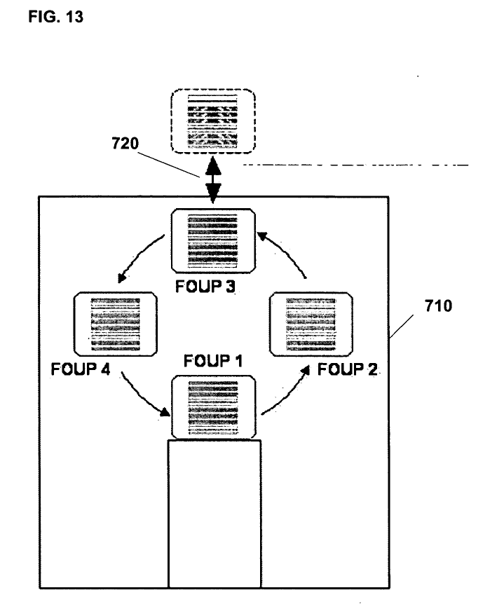

A small footprint, high throughput wafer handler for the parallel wafer processing reactor 10 is illustrated schematically in FIGS. 13-15. A front view of the wafer handler is shown in FIG. 13. A FOUP (front opening unified pod) that is either the source or destination of wafers being processed can be randomly or sequentially accessed from a buffer of FOUPs 710 and positioned at the load port. An overhead transport system (OHT) 720 or similar factory automation system can remove or place FOUPs in the buffer 710. The mode of wafer transfer from the FOUP to the process chamber depends on the architecture of the wafer handler.

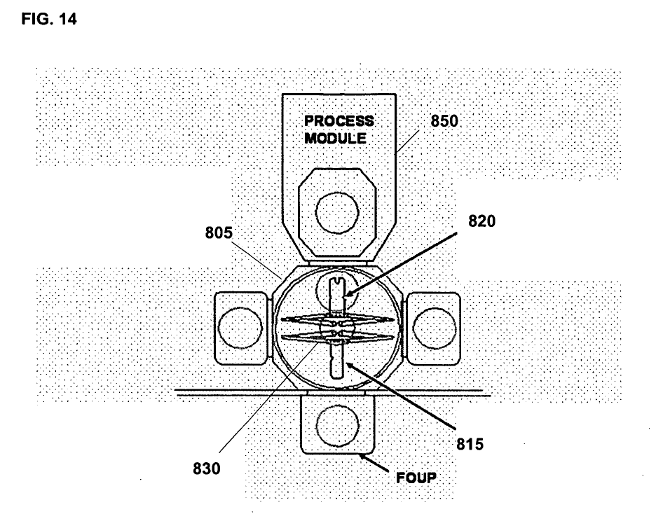

In the architecture shown in FIG. 14, the wafer handler chamber 805 and the load locks are vented with filtered dry N₂ (or an inert gas) to atmospheric pressure. One of the arms 815 of the dual ended robot 830 with multiple end effectors transfers multiple wafers from the FOUP to the internal load lock. For a process chamber 850 with a capacity of 52 wafers, each load lock could have a capacity of 26 wafers. After the first load lock has been loaded, the next FOUP containing wafers to be processed is moved to the load port and the robot 830 transfers the wafers to the second load lock. Following wafer transfer, the load locks and the wafer handler chamber 805 are cycle pump/purged and pumped to a base or wafer transfer pressure. A second arm 820 of the dual ended robot 830 then moves the wafers from each of the load locks to the process chamber 850. If the process chamber 850 is configured with four wafers per susceptor pair, 1, 2 or 4 wafers can be moved at a time. The inter-wafer pitch in the load locks is adjustable to match the inter-wafer pitch in the FOUP and the process chamber 850. Also, in order to reduce the z-axis travel of the robot 830 during wafer transfer, the FOUP, load lock cassette and boat in the process chamber 850 can be translated up and down so that the wafers to be transferred lie in the plane of the robot arm 815, 820. After the wafers are loaded, the gate valve isolating the process chamber 850 from the wafer handler chamber 805 is closed and the process module begins wafer processing. When wafer processing is completed, the gate valve isolating the process chamber 850 from the wafer handler chamber 805 is opened and wafers are transferred to the load locks. Once wafer transfer has been completed, and the gate valve is closed, each load lock can be pumped/purged to cool down the wafers to an acceptable temperature (usually <100° C.), before the load lock and wafer handler chamber 805 are vented to atmospheric pressure. The wafers can then be transferred to each of the FOUPs. Generally the wafers have to be returned to the FOUPs from which the wafers originated. This cycle then repeats for the next set of wafers to be processed.

The process chamber 850 remains idle from the point when the first set of wafers has exited the process chamber 850, and the next set of wafers is loaded into the process chamber 850. Thus the cycle time for a set of wafers to be processed is the sum of the processing time and the total wafer handling time. For short processes, the total wafer handling time may exceed the process time which limits the maximum throughput available.

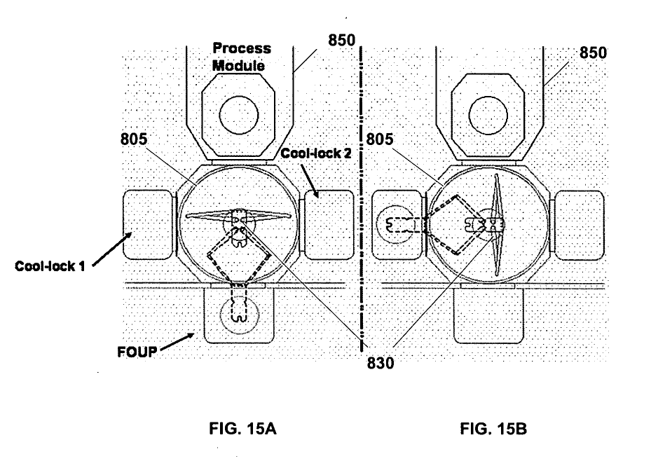

FIG. 15A shows a wafer handler in one state and FIG. 15B shows a wafer handler in another state. In the wafer architecture shown here, the robot 830 moves one or two wafers at a time from either FOUP to the load locks, but performs a ripple swap between the load lock and the process chamber 850. In a ripple swap, a processed wafer in the process chamber 850 is exchanged with an unprocessed wafer from the load lock. Once all the wafers in the process chamber 850 have been exchanged with unprocessed wafers, the process chamber 850 resumes processing. While the process chamber 850 is processing wafers, processed wafers from the load locks are moved to the FOUPs preferably two at a time and the next set of wafers to be processed are transferred (again preferably two at a time) from the FOUP to the load lock. These wafers are then available for exchanging with wafers in the process chamber 850 once the process chamber 850 completes processing. In this architecture, the cycle time for a set of wafers to be processed is the sum of the processing time and the duration of the ripple swap between both load locks and the process chamber 850. Since the latter is only a small fraction of the total wafer handling time, a higher throughput can be achieved in continuous operation. In the continuous mode of operation, FOUPs that have completed processing are immediately off loaded and replaced with FOUPs that have yet to be processed.

While the foregoing is directed to embodiments of the present invention, other and further embodiments of the invention may be devised without departing from the basic scope thereof, and the scope thereof is determined by the claims that follow.

1. A carrier for supporting a plurality of wafers in a reactor, comprising:
a vertical stack of horizontally oriented thermal plates; and
a wafer support positioned between a pair of the thermal plates for supporting at least two wafers.

2. The carrier according to claim 1, wherein the wafer support includes two spacers, each with at least two shoulders formed thereon for supporting said at least two wafers at opposite ends.

3. The carrier according to claim 1, wherein the number of wafers supported between each pair of the thermal plates is the same.

4. The carrier according to claim 1, wherein the number of wafers supported between each pair of the thermal plates is different.

5. The carrier according to claim 1, wherein the wafer support includes three spacers, each with at least two shoulders formed thereon for supporting said at least two wafers at first, second and third ends of the wafers.

6. The carrier according to claim 1, wherein the wafer support includes at least two spacers inserted between each pair of the thermal plates.

7. A carrier for supporting a plurality of wafers in a reactor, comprising:
a vertical stack of horizontally oriented annular rings; and
a wafer support positioned between a pair of the annular rings for supporting at least two wafers.

8. The carrier according to claim 7, wherein the wafer support includes two spacers, each with at least two shoulders formed thereon for supporting said at least two wafers at opposite ends.

9. The carrier according to claim 7, wherein the number of wafers supported between each pair of the annular rings is the same.

10. The carrier according to claim 7, wherein the number of wafers supported between each pair of the annular rings is different.

11. The carrier according to claim 7, wherein the wafer support includes three spacers, each with at least two shoulders formed thereon for supporting said at least two wafers at first, second and third ends of the wafers.

12. The carrier according to claim 7, wherein the wafer support includes at least two spacers inserted between each pair of the annular rings.

13. A reactor for processing substrates, comprising:
a chamber in which the substrates are processed; and
a substrate carrier having a plurality of horizontally arranged susceptors and a support for holding at least two substrates disposed between a pair of said susceptors.

14. The reactor according to claim 13, wherein the susceptors comprise thermal plates.

15. The reactor according to claim 13, wherein the susceptors comprise annular rings.

16. The reactor according to claim 13, wherein the number of substrates supported between each pair of the susceptors is the same.

17. The reactor according to claim 13, wherein the number of substrates supported between each pair of the susceptors is different.

18. The reactor according to claim 13, wherein the support includes two spacers, each with at least two shoulders formed thereon for supporting said at least two substrates at opposite ends.

19. The reactor according claim 18, wherein the spacers engage with lower recesses provided on a susceptor positioned above the spacers and has a lower opening that engages with upper posts provided on a susceptor positioned below the spacers.

20. The reactor according to claim 13, wherein the support includes three spacers, each with at least two shoulders formed thereon for supporting said at least two wafers at first, second and third ends of the wafers.
